(19) United States
(12) Patent Application Publication
(10) Pub. No.: US 2013/0163789 A1
(43) Pub. Date: Jun. 27, 2013

(54) AMPLIFIER AND AMPLIFYING METHOD

(71) Applicants: Seigen Maeno, Toyota-shi (JP); Hiroshi Tomonaga, Nagoya-shi (JP)

(72) Inventors: Seigen Maeno, Toyota-shi (JP); Hiroshi Tomonaga, Nagoya-shi (JP)

(21) Appl. No.: 13/819,810

(22) PCT Filed: Sep. 5, 2011
(86) PCT No.: PCT/IB11/02050

§ 371 Date: Feb. 28, 2013

(30) Foreign Application Priority Data
Sep. 6, 2010 (JP) 2010-199390

(51) Int. Cl. H03F 3/68

(52) U.S. Cl. CPC H03F 3/68
USPC 381/120

(57) ABSTRACT

An amplifier that modulates a carrier frequency according to a digital signal and amplifies the modulated signal includes a determining portion that determines at least one of a sound quality required for the digital signal, a sound source of the digital signal, and a type of sound of the digital signal, a carrier frequency setting portion that sets a carrier frequency according to a result of the determination, and a pulse-width modulating portion that pulse-width modulates the carrier frequency according to the digital signal.

### BACKGROUND OF THE INVENTION

1. Field of the invention

The invention relates to an amplifier, and more particularly, a D-class amplifier.

2. Description of Related Art

FIG. 1 is a view of a D-class amplifier.

This D-class amplifier includes a gate driver, a transistor Tr1, a transistor Tr2, and a LC filter.

According to the D-class amplifier shown in FIG. 1, the gate driver operates while the power is on. Because the gate driver operates, a switching signal is generated on the output side even when there is no input signal. The duty ratio of this switching signal is 50%, for example. This switching signal is consumed as reactive power by the LC filter that is formed by L1 and C1.

With a D-class amplifier, because the gate driver operates even when there is no input signal, a switching signal is generated on the output side, and this switching signal is consumed as reactive power. This reactive power is not desirable from the viewpoint of low power consumption.

In particular, when used as an on-board amplifier, the power supply of the amplifier must be turned on in order to generate voice interruptions of a navigation system or the like, even when the audio is set to the off mode. In this case, although it is sufficient to turn on only the channel nearest the driver (such as the right-front) for the driver to be able to hear, the power to all of the channels ends up being turned on, which ends up wasting operating power.

Also, with a D-class amplifier, a high carrier frequency is undesirable in order to obtain high-quality audio characteristics. However, with a D-class amplifier, sound that does not need to be high-quality, such as a navigation voice, is also amplified. Modulating a carrier frequency higher for sound that does not need to be high-quality is not desirable from the viewpoint of low power consumption. A high carrier frequency increases the reactive power that is consumed as switching loss, i.e., switching voltage. An increase in switching loss results in a decrease in switching efficiency, which leads to an increase in power consumption.

The sound quality for emergency audio from a navigation system or the like does not need to be the same sound quality as a CD for example.

### SUMMARY OF THE INVENTION

The invention provides an amplifier and amplifying method capable of reducing power consumption.

A first aspect of the invention relates to an amplifier that modulates a carrier frequency according to a digital signal and amplifies the modulated signal. This amplifier includes a determining portion that determines at least one of a sound quality required for the digital signal, a sound source of the digital signal, and a type of sound of the digital signal, a carrier frequency setting portion that sets a carrier frequency according to a result of the determination by the determining portion, and a pulse-width modulating portion that pulse-width modulates the carrier frequency set by the carrier frequency setting portion, according to the digital signal.

A second aspect of the invention relates to an amplifier. This amplifier modulates a carrier frequency according to a digital signal and amplifies the modulated signal. This amplifier includes an input signal determining portion that determines whether the digital signal is being input, a determining portion that determines at least one of a sound quality required for the digital signal, a sound source of the digital signal, and a type of sound of the digital signal, a carrier frequency setting portion that sets a carrier frequency according to a result of the determination by the determining portion, and a plurality of pulse-width modulating portions that pulse-width modulate the carrier frequency set by the carrier frequency setting portion, according to the digital signal. The carrier frequency setting portion sets a carrier frequency corresponding to each of the plurality of pulse-width modulating portions.

A third aspect of the invention relates to a method by which an amplifier modulates a carrier frequency according to a digital signal and amplifies the modulated signal. This method includes determining at least one of a sound quality required for the digital signal, a sound source of the digital signal, and a type of sound of the digital signal, setting a carrier frequency according to a result of the determination, and pulse-width modulating the set carrier frequency according to the digital signal.

A fourth aspect of the invention relates to a method by which an amplifier modulates a carrier frequency according to a digital signal and amplifies the modulated signal. This method includes determining whether the digital signal is being input, determining at least one of a sound quality required for the digital signal, a sound source of the digital signal, and a type of sound of the digital signal, setting a carrier frequency according to a result of the determination, and pulse-width modulating the set carrier frequency according to the digital signal, by a corresponding pulse-width modulating portion, from among a plurality of pulse-width modulating portions that pulse-width modulate a carrier frequency according to the digital signal. In setting the carrier frequency, a carrier frequency corresponding to each of the plurality of pulse-width modulating portions is set.

The amplifier and amplifying method described above are able to reduce power consumption.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a view of an example of a D-class amplifier;

FIG. 2 is a functional block diagram (part 1) illustrating an example of an amplifier according to an example embodiment of the invention;

FIG. 3 is a functional block diagram (part 2) illustrating an example of the amplifier according to the example embodiment;

FIG. 4 is a flowchart illustrating the operation of a vehicle communication system according to the example embodiment; and

FIG. 5 is a functional block diagram of an example of the amplifier according to the example embodiment.

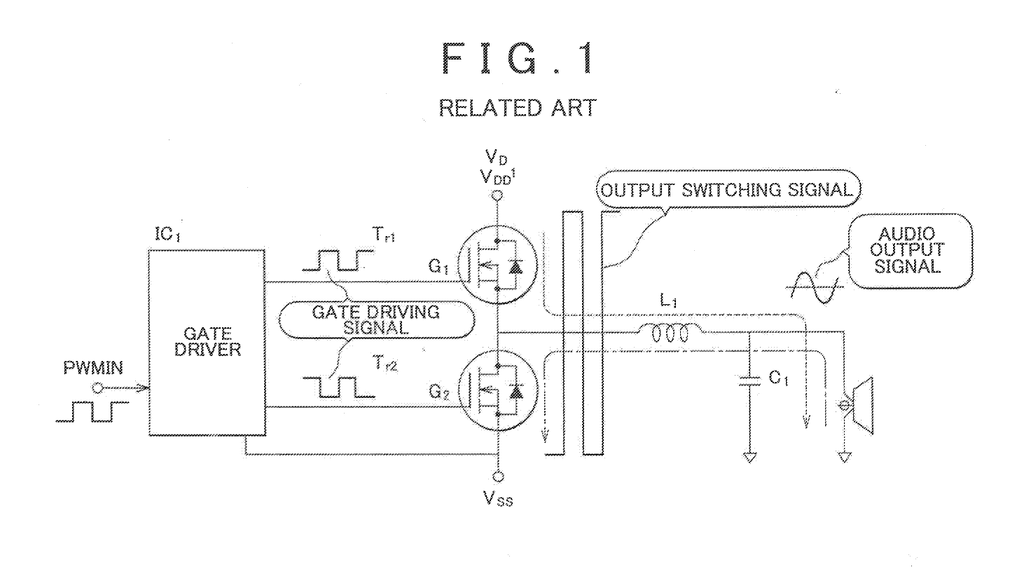

### DETAILED DESCRIPTION OF EMBODIMENTS

Next, a mode for carrying out the invention will be described with reference to the accompanying drawings based on the example embodiments described below. In all of the drawings illustrating the example embodiments, portions having the same function will be denoted by the same reference characters and redundant descriptions of those portions will be omitted.

### Example Embodiments

<Amplifier>

An amplifier 100 is provided in a device. This device includes on-board devices and audio devices and the like. The audio devices may include portable audio devices and devices capable of playing CDs and radio or the like. The audio devices may also include devices capable of playing data compressed according to a predetermined compression sound file format. This format may include MP3.

In this example embodiment, a case in which the amplifier 100 is provided in an on-board device will be described as an example. This on-board device is able to output various sound and/or voice (hereinafter simply referred to as “sound”). For example, the sound source of sound output from the on-board device may be a DVD (Digital Versatile Disk), a CD or AM radio. Sound from DVDs and CDs must be high quality, while sound from AM radio does not need to be as high quality as sound from DVDs and CDs. Sound that has been converted to a digital signal may also be input to the amplifier 100.

This amplifier 100 determines at least one of the sound quality required for the digital signal, the sound source of the digital signal, and the type of sound of the digital signal. For example, the required sound quality may be determined based on the sound source of the digital signal. The sound source may be, for example, a DVD, terrestrial digital broadcasting, a CD, satellite digital television, FM radio, AM radio, or voice guidance and operating sounds of a navigation system or the like. The sound quality may include high quality, medium quality, and low quality. These classifications of sound quality are only examples. That is, the sound quality may also be classified into two types of sound quality or four or more types of sound quality. When sound quality is divided according to the sound source, for example, DVDs, terrestrial digital broadcasting, CDs, and satellite digital television all require high sound quality, so high sound quality may be determined for these. On the other hand, FM radio, for example, requires only medium sound quality, so medium sound quality may be determined for FM radio. In contrast, low sound quality is sufficient for AM radio and voice guidance and operating sounds of a navigation system, so low sound quality may be determined for these. In this example embodiment, a case in which the required sound quality is determined based on the sound source is given as an example of determining at least one of the sound quality required for the digital signal, the sound source of the digital signal, and the type of sound of the digital signal is determined. However, the invention is not limited to this example. That is, the sound quality required for a digital signal, the sound source of the digital signal, and the type of sound of the digital signal may be determined separately.

The amplifier 100 changes a carrier frequency to be used when modulating the carrier frequency according to the digital signal, according to at least one of the sound quality required for the digital signal, the sound source of the digital signal, and the type of sound of the digital signal. This carrier frequency may also be referred to as a switching frequency.

The amplifier 100 may control switching voltage to be used when amplifying the carrier frequency modulated according to the digital signal, according to at least one of the sound quality required for the digital signal, the sound source of the digital signal, and the type of sound of the digital signal. It is sufficient that only one of the carrier frequency and the switching frequency be controlled. As the carrier frequency becomes higher, the sound quality also becomes higher but the power consumption increases. Conversely, as the carrier frequency becomes lower, the sound quality also becomes lower but the power consumption decreases.

With this amplifier 100, the same carrier frequency and/or the switching voltage are not uniformly set for the digital signal. Instead, the carrier frequency and/or the switching voltage is set according to at least one of the sound quality required for the digital signal, the sound source of the digital signal, and the type of sound of the digital signal.

More specifically, when high sound quality is required, such as when the sound source is a DVD, terrestrial digital broadcasting, a CD, or satellite digital television, control is performed to obtain a high switching frequency and/or a high switching voltage. Also, when medium sound quality is required, such as when the sound source is FM radio, control is performed to obtain a medium switching frequency and/or a medium switching voltage. Also, when low sound quality is required, such as when the sound source is AM radio or voice guidance and operating sounds of a navigation system, control is performed to obtain a low switching frequency and/or a low switching voltage.

Also, this on-board device is able to turn of the audio function. More specifically, the on-board device is able to turn off a function such as a DVD, terrestrial digital broadcasting, a CD, satellite digital television, FM radio, and AM radio and the like. When the audio function is turned off, control is performed to obtain a low switching frequency and/or a low switching voltage. Also, input of the switching frequency and/or the switching voltage may be stopped when the audio function is turned off.

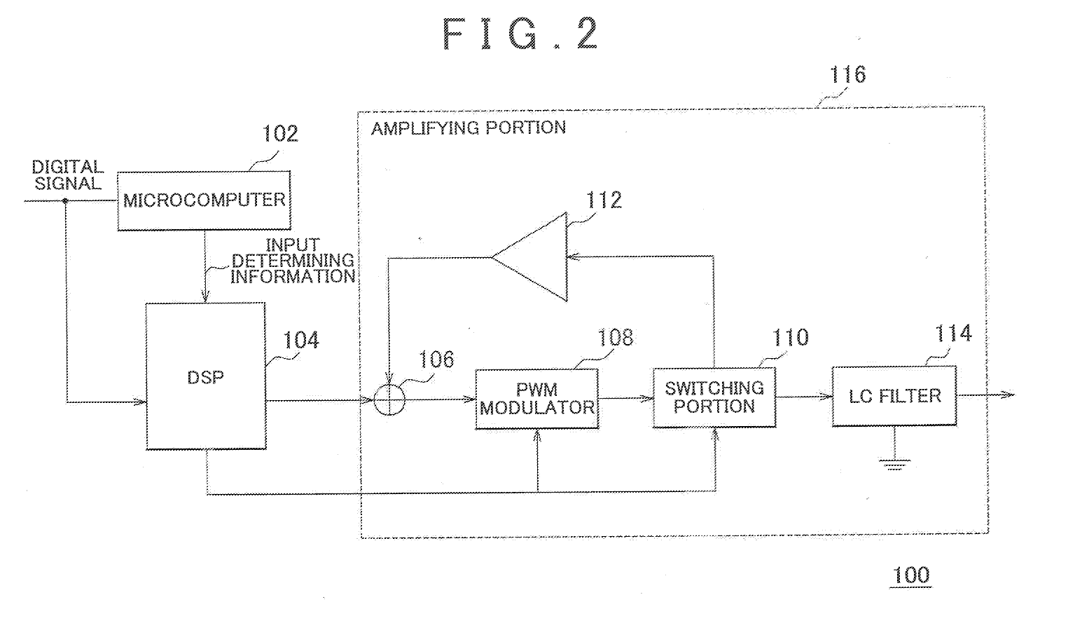

FIG. 2 is a view of the amplifier 100 according to this example embodiment, and shows mainly the hardware structure.

The amplifier 100 has a microcomputer 102.

This microcomputer 102 determines whether there is an input signal. A digital signal is input to the microcomputer 102. This digital signal is a signal to which sound has been converted. The sound source of this sound may be a DVD, terrestrial digital broadcasting, a CD, satellite digital television, FM radio, AM radio, or voice guidance and operating sounds of a navigation system or the like.

When a digital signal is input, the microcomputer 102 outputs input determining information that indicates whether a digital signal is being input, to a Digital Signal Processer (DSP) 104.

The amplifier 100 includes this DSP 104. The DSP 104 is connected to the microcomputer 102. A digital signal is input to the DSP 104. This digital signal is the same signal as the signal that is to be input to the microcomputer 102. The input determining information is input to the DSP 104 from the microcomputer 102.

The DSP 104 determines whether a digital signal is being input based on an input determining signal that is to be input from the microcomputer 102. If it is determined that a digital signal is being input, a digital signal is being input to the DSP 104, so at least one of the sound quality required for the digital signal, the sound source of the digital signal, and the type of sound of the digital signal is determined.

The DSP 104 sets the carrier frequency to be used when pulse-width modulating the carrier frequency according to the digital signal, based on at least one of the sound quality required for the digital signal, the sound source of the digital signal, and the type of sound of the digital signal. When the carrier frequency to be used when pulse-width modulating the carrier frequency according to the digital signal is set based on at least one of the sound quality required for the digital signal, the sound source of the digital signal, and the type of sound of the digital signal, pulse width modulation to obtain quality better than that which is required for the sound is not performed. Because pulse width modulation to obtain quality better than that which is required for the sound is not performed, the power consumed by a PWM modulator 108 can be reduced, and as a result, the power consumption of the amplifier 100 can be reduced.

Also, the DSP 104 sets the switching voltage to be used when amplifying the carrier frequency modulated according to the digital signal, based on at least one of the sound quality required for the digital signal, the sound source of the digital signal, and the type of sound of the digital signal. When the switching voltage to be used when amplifying the carrier frequency modulated according to the digital signal is set based on at least one of the sound quality required for the digital signal, the sound source of the digital signal, and the type of sound of the digital signal, amplification to obtain quality better than that which is required for the sound is not performed. Because amplification to obtain quality better than that which is required for the sound is not performed, the power consumed by a switching portion 110 can be reduced, and as a result, the power consumption of the amplifier 100 can be reduced.

The DSP 104 outputs a digital signal to the PWM modulator 108. The DSP 104 outputs a carrier frequency to the PWM modulator 108. The DSP 104 outputs a switching voltage to the switching portion 110.

The DSP 104 may also set the carrier frequency, even when it is determined that a digital signal is not being input. The same carrier frequency as the carrier frequency to be set for low sound quality may be set as the carrier frequency to be set when a digital signal is not being input, or oscillation may also be stopped. Setting the same carrier frequency as the carrier frequency to be set for low sound quality, or stopping oscillation, when a digital signal is not being input enables the power consumed by the PWM modulator 108 to be reduced, thereby enabling the power consumed by the amplifier 100 to be reduced. The PWM modulator 108 may also be turned off when a digital signal is not being input. Turning off the PWM modulator 108 when a digital signal is not being input enables the power consumed by the PWM modulator 108 to be further reduced, which in turn enables the power consumed by the amplifier 100 to be further reduced.

Further, the DSP 104 may also set the switching voltage to be used, even when it is determined that a digital signal is not being input. The same switching voltage as the switching voltage to be set for low sound quality may be set as the switching voltage to be set when a digital signal is not being input. Setting the same switching voltage as the switching voltage to be set for low sound quality when a digital signal is not being input enables the power consumed by the switching portion 110 to be reduced, thereby enabling the power consumed by the amplifier 100 to be reduced. The switching portion 110 may also be turned off when a digital signal is not being input. Turning off the switching portion 110 when a digital signal is not being input enables the power consumed by the switching portion 110 to be further reduced, which in turn enables the power consumed by the amplifier 100 to be further reduced.

<Function of the Amplifier>

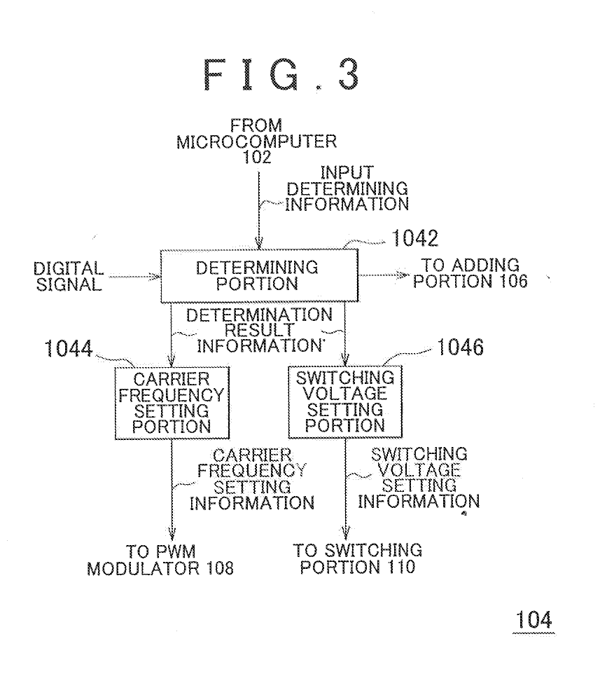

FIG. 3 is a view of the function of the amplifier 100, and shows mainly the function of the DSP 104.

The DSP 104 has a determining portion 1042. A digital signal is input to the determining portion 1042. Input determining information is input to the determining portion 1042 from the microcomputer 102. The determining portion 1042 outputs the digital signal to an adding portion 106.

Upon receiving an input determining signal from the microcomputer 102, the determining portion 1042 determines whether this input determining signal is information indicating that a digital signal is being input. If the input determining signal is information indicating that a digital signal is being input, then a digital signal is being input, so the determining portion 1042 determines at least one of the sound quality required for the digital signal, the sound source of the digital signal, and the type of sound of the digital signal. For example, the determining portion 1042 determines the sound source of the digital signal based on the digital signal to be input. The determining portion 1042 determines the required sound quality based on the sound source of the digital signal. This sound source may be a DVD, terrestrial digital broadcasting, a CD, satellite digital television, FM radio, AM radio, or voice guidance and operating sounds of a navigation system or the like. The sound quality may include high sound quality, medium sound quality, and low sound quality. The determining portion 1042 inputs determination result information indicative of the result of the determination of at least one of the sound quality required for the digital signal, the sound source of the digital signal, and the type of sound of the digital signal. For example, the determination result information may include information indicating that the sound quality required for the digital signal is high sound quality, medium sound quality, or low sound quality.

If, on the other hand, the input determining signal is not information indicating that a digital signal is being input, then the determining portion 1042 notifies a carrier frequency setting portion 1044 and a switching voltage setting portion 1046 that a digital signal is not being input.

The DSP 104 includes the carrier frequency setting portion 1044. Determination result information is input to the carrier frequency setting portion 1044 from the determining portion 1042. The carrier frequency setting portion 1044 sets a carrier frequency to be used when modulating the carrier frequency according to the digital signal, based on the determination result information from the determining portion 1042. For example, the sound quality required for the digital signal may be associated with a carrier frequency to be set for this sound quality. More specifically, carrier frequencies to be used when the sound quality is high, medium, and low may be associated with these sound qualities, respectively. A high frequency may be associated with high sound quality, a medium frequency may be associated with medium sound quality, and a low frequency may be associated with low sound quality. When a sound quality is associated with a carrier frequency, the carrier frequency corresponding to the sound quality is selected and set. The carrier frequency setting portion 1044 outputs carrier frequency setting information indicative of the set carrier frequency to the PWM modulator 108. Also, a sound source may be associated with a carrier frequency that corresponds to this sound source. When a sound source is associated with a carrier frequency that corresponds to this sound source, the carrier frequency corresponding to the sound source is selected and set.

Also, upon being notified by the determining portion 1042 that a digital signal is not being input, the carrier frequency setting portion 1044 selects and sets the carrier frequency corresponding to low sound quality as the carrier frequency to be used. Alternatively, oscillation may be stopped. The carrier frequency setting portion 1044 then outputs carrier frequency setting information indicative of the set carrier frequency to the PWM modulator 108. Also, if the carrier frequency setting portion 1044 is notified by the determining portion 1042 that a digital signal is not being input, the carrier frequency setting portion 1044 may output a signal to turn off the PWM modulator 108 to the PWM modulator 108.

The DSP 104 includes the switching voltage setting portion 1046. The switching voltage setting portion 1046 inputs determination result information from the determining portion 1042. The switching voltage setting portion 1046 sets the switching voltage to be used when amplifying the carrier frequency that has been pulse-width modulated according to a digital signal, based on the determination result information from the determining portion 1042. For example, the sound quality required for the digital signal may be associated with a switching voltage to be set according to this sound quality. More specifically, switching voltages to be used when the sound quality is high, medium, and low may be associated with these sound qualities, respectively. A high voltage may be associated with high sound quality, a medium voltage may be associated with medium sound quality, and a low voltage may be associated with low sound quality. When a sound quality is associated with a switching voltage, the switching voltage corresponding to the sound quality is selected and set. The carrier frequency setting portion 1044 outputs switching voltage setting information indicative of the set switching voltage to the PWM modulator 108. Also, a sound source may be associated with a switching voltage that corresponds to this sound source. When a sound source is associated with a switching voltage that corresponds to this sound source, the switching voltage corresponding to the sound source is selected and set.

Also, upon being notified by the determining portion 1042 that a digital signal is not being input, the switching voltage setting portion 1046 selects and sets the switching voltage corresponding to low sound quality as the switching voltage to be used. The switching voltage setting portion 1046 then outputs switching voltage setting information indicative of the set switching voltage to the switching portion 110. Also, if the switching voltage setting portion 1046 is notified by the determining portion 1042 that a digital signal is not being input, the switching voltage setting portion 1046 may output a signal to turn off the switching portion 110 to the switching portion 110.

The amplifier 100 includes the adding portion 106. This adding portion 106 is connected to the DSP 104. The adding portion 106 adds a signal to be input from the DSP 104 to a signal that is fed back via an operational amplifier 112. A signal in which the carrier frequency that has been pulse-width modulated according to the digital signal has been inverted and amplified, and then added to a digital signal, is input by the PWM modulator 108.

The amplifier 100 includes the PWM modulator 108. The PWM modulator 108 is connected to the adding portion 106 and the DSP 104. The PWM modulator 108 performs Pulse-Width Modulation (PWM) on a carrier frequency according to a digital signal to be input from the adding portion 106, according to carrier frequency setting information to be input from the DSP 104. More specifically, the PWM modulator 108 performs the modulation by changing the duty ratio of a pulse wave to be input from the adding portion 106. For example, the PWM modulator 108 has a plurality of processing portions that perform pulse-width modulation according to different operational expressions. For example, the PWM modulator 108 may have a processing portion that pulse-width modulates a carrier frequency corresponding to high sound quality, a processing portion that pulse-width modulates a carrier frequency corresponding to medium sound quality, and a processing portion that pulse-width modulates a carrier frequency corresponding to low sound quality. More specifically, the PWM modulator 108 performs pulse-width modulation according to carrier frequency setting information to be input from the DSP 104. The PWM modulator 108 then outputs a signal after pulse-width modulation (hereinafter referred to as a “modulated signal”) to the switching portion 110.

The amplifier 100 includes the switching portion 110. The switching portion 110 is connected to the PWM modulator 108 and the DSP 104. The switching portion 110 amplifies the modulated signal to be input from the PWM modulator 108, according to switching voltage setting information to be input from the DSP 104. The switching portion 110 then outputs the amplified modulated signal to the operational amplifier 112 and a LC filter 114. For example, the switching portion 110 has a plurality of processing portions that perform amplification according to different operational expressions. For example, the switching portion 110 may have a processing portion that performs amplification according to a switching voltage corresponding to high sound quality, a processing portion that performs amplification according to a switching voltage corresponding to medium sound quality, and a processing portion that performs amplification according to a switching voltage corresponding to low sound quality. More specifically, the switching portion 110 performs amplification according to switching voltage setting information to be input from the DSP 104. The switching portion 110 then outputs a modulated signal after amplification (hereinafter simply referred to as an “amplified modulated signal”) to the operational amplifier 112 and the LC filter 114.

The amplifier 100 includes the operational amplifier 112. This operational amplifier 112 is connected to the switching portion 110 and the adding portion 106. The operational amplifier 112 inverts and amplifies an amplified modulated signal to be input from the switching portion 110, and outputs the resultant signal to the adding portion 106.

The amplifier 100 includes the LC filter 114. This LC filter 114 is connected to the switching portion 110. The LC filter 114 passes along a signal of a predetermined bandwidth from the amplified modulated signal from the switching portion 110. The signal that passes through the LC filter 114 undergoes predetermined processing and is then output from a speaker, not shown, as sound.

<Operation of the Amplifier>

FIG. 4 is a view illustrating an example of the operation of the amplifier.

The amplifier 100 determines whether a digital signal is being input (step S402). For example, the microcomputer 102 determines whether a digital signal is being input.

If it is determined that a digital signal is being input (i.e., YES in step S402), the amplifier 100 determines at least one of the sound quality required for the digital signal, the sound source of the digital signal, and the type of sound of the digital signal (step S404). For example, the determining portion 1042 determines at least one of the sound quality required for the digital signal, the sound source of the digital signal, and the type of sound of the digital signal.

The amplifier 100 then sets a carrier frequency (step S406). For example, the carrier frequency setting portion 1044 sets a carrier frequency to be used when pulse-width modulating the carrier frequency according to the digital signal, according to the result of the determination in step S404.

The amplifier 100 then sets the switching voltage (step S408). For example, the switching voltage setting portion 1046 sets the switching voltage to be used when amplifying a carrier frequency that has been pulse-width modulated according to the digital signal, according to the result of the determination in step S404.

The amplifier 100 then pulse-width modulates the carrier frequency set in step S406, according to the digital signal (step S410). For example, the PWM modulator 108 pulse-width modulates the carrier frequency set by the carrier frequency setting portion 1044, according to the digital signal.

The amplifier 100 amplifies the carrier frequency modulated according to the digital signal, according to the switching voltage set in step S408 (step S412). For example, the switching portion 110 amplifies the carrier frequency modulated according to the digital signal, according to the switching voltage input from the switching voltage setting portion 1046.

A signal of a predetermined bandwidth is extracted by the LC filter 114 from the modulated signal that has been amplified by the switching portion 110. The signal extracted by the LC filter 114 undergoes predetermined processing and is then output from a speaker, not shown, as sound.

If, on the other hand, it is not determined that a digital signal is being input (i.e., NO in step S402), the process proceeds on to step S406 without step S404 being performed.

In step S404, a carrier frequency to be set when a digital signal is not being input is set. In step S406, a switching voltage to be set when a digital signal is not being input is set.

<Modified Example>

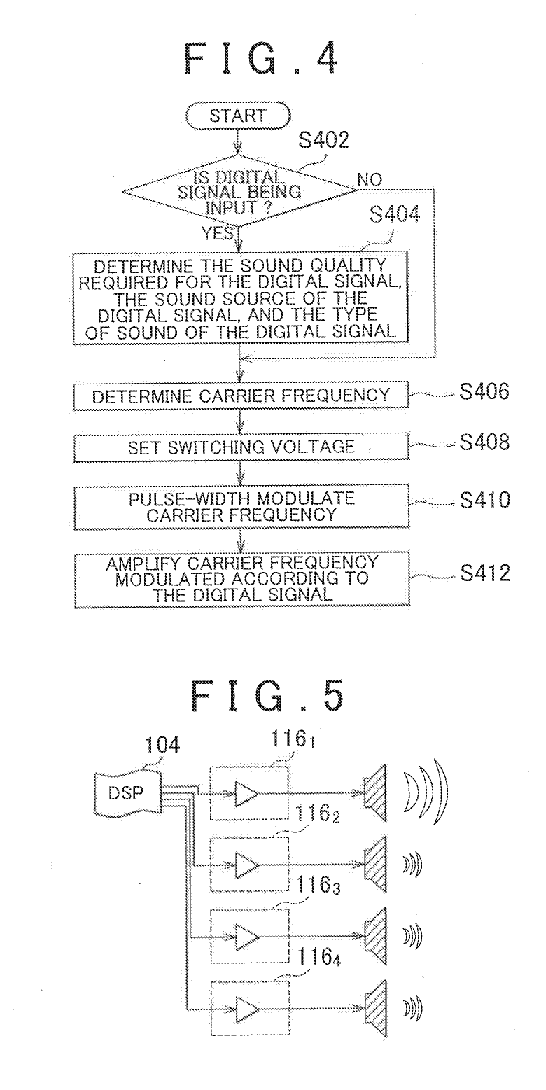

FIG. 5 is a view of the amplifier 100 according to a modified example.

The amplifier 100 has a plurality of amplifying portions 116 in the amplifier described with reference to FIG. 2. FIG. 5 shows a case in which there are four amplifying portions 116₁ to 116₄. However, there may also be two or three amplifying portions, or five or more amplifying portions. Each of these amplifying portions 116₁ to 116₄ includes an adding portion 106, a PWM modulator 108, a switching portion 110, an operational amplifier 112, and a LC filter 114. In other words, the amplifier 100 has a plurality of channels. The amplifier 100 is able to set a channel to output sound, from among the plurality of channels.

For example, the amplifying portion 116₁ amplifies sound to be output from a speaker that is to be located at the right front. Also, the amplifying portion 116₂ amplifies sound to be output by a speaker that is to be located at the left front. Also, the amplifying portion 116₃ amplifies sound to be output by a speaker that is to be located at the right rear, and the amplifying portion 116₄ amplifies sound to be output by a speaker that is to be located at the left rear.

The DSP 104 is connected to the plurality of amplifying portions 116₁ to 116₄.

The DSP 104 determines whether a digital signal is being input based on an input determining signal to be input from the microcomputer 102. If it is determined that a digital signal is being input, then a digital signal is being input to the DSP 104, so the DSP 104 determines at least one of the sound quality required for the digital signal, the sound source of the digital signal, and the type of sound of the digital signal. For example, the determining portion 1042 determines whether a digital signal is being input based on the input determining signal. If it is determined that a digital signal is being input, the determining portion 1042 determines at least one of the sound quality required for the digital signal, the sound source of the digital signal, and the type of sound of the digital signal.

The DSP 104 sets the carrier frequency to be used when modulating a carrier frequency according to the digital signal, based on at least one of the sound quality required for the digital signal, the sound source of the digital signal, and the type of sound of the digital signal. For example, the carrier frequency setting portion 1044 sets the carrier frequency to be used when modulating a carrier frequency according to the digital signal, based on at least one of the sound quality required for the digital signal, the sound source of the digital signal, and the type of sound of the digital signal.

Also, the DSP 104 sets the switching voltage to be used when amplifying a carrier frequency modulated according to the digital signal, based on at least one of the sound quality required for the digital signal, the sound source of the digital signal, and the type of sound of the digital signal. For example, the switching voltage setting portion 1046 sets the switching voltage to be used when amplifying a carrier frequency modulated according to the digital signal, based on at least one of the sound quality required for the digital signal, the sound source of the digital signal, and the type of sound of the digital signal.

The DSP 104 outputs a digital signal to the PWM modulator 108 of the amplifying portion that is to output the digital signal, from among the four amplifying portions 116₁ to 116₄. For example, the carrier frequency setting portion 1044 outputs a digital signal to the PWM modulator 108 of the amplifying portion that is to output the digital signal.

The DSP 104 outputs a carrier frequency to the PWM modulator 108 of the amplifying portion that is to output the digital signal, from among the four amplifying portions 116₁ to 116₄. For example, the carrier frequency setting portion 1044 outputs a carrier frequency to the PWM modulator 108 of the amplifying portion that is to output the digital signal.

The DSP 104 outputs a switching voltage to the switching portion 110 of the amplifying portion that is to output the digital signal, from among the four amplifying portions 116₁ to 116₄. For example, the switching voltage setting portion 1046 outputs a switching voltage to the switching portion 110 of the amplifying portion that is to output the digital signal.

The DSP 104 may also set the same carrier frequency as the carrier frequency to be set when the sound quality is low, in the PWM modulator 108 of an amplifying portion other than the amplifying portion that is to output the digital signal, or may stop oscillation. For example, the carrier frequency setting portion 1044 may output the same carrier frequency as the carrier frequency to be set when the sound quality is low, to the PWM modulator 108 of an amplifying portion other than the amplifying portion that is to output the digital signal. Also, the DSP 104 may output a signal to turn off the PWM modulator 108 to the PWM modulator 108 of an amplifying portion other than the amplifying portion that is to output the digital signal. For example, the carrier frequency setting portion 1044 outputs a signal to turn off the PWM modulator 108 to the PWM modulator 108 of an amplifying portion other than the amplifying portion that is to output the digital signal.

The DSP 104 may also set the same switching voltage as the switching voltage to be set when the sound quality is low, in the switching portion 110 of an amplifying portion other than the amplifying portion that is to output the digital signal. For example, the switching voltage setting portion 1046 outputs the same switching voltage as the switching voltage to be set when the sound quality is low, to the switching portion 110 of an amplifying portion other than the amplifying portion that is to output the digital signal. Also, the DSP 104 may output a signal to turn off the switching portion 110 to the switching portion 110 of an amplifying portion other than the amplifying portion that is to output the digital signal. For example, the switching voltage setting portion 1046 may output a signal to turn off the switching portion 110 to the switching portion 110 of an amplifying portion other than the amplifying portion that is to output the digital signal.

Also, the DSP 104 may set a carrier frequency to be used in the amplifying portions 116₁ to 116₄, or stop oscillation, even if it is determined that a digital signal is not being input. The same carrier frequency as the carrier frequency to be set when the sound quality is low may be set as the carrier frequency to be set when a digital signal is not being input. For example, the carrier frequency setting portion 1044 sets the same carrier frequency as the carrier frequency to be set when the sound quality is low. Also, the DSP 104 may output a signal to turn off the PWM modulators 108 to the PWM modulators 108 of the amplifying portions 116₁ to 116₄. For example, the carrier frequency setting portion 1044 outputs a signal to turn off the PWM modulators 108 of the amplifying portions 116₁ to 116₄.

Also, the DSP 104 may set the switching voltage to be used in the amplifying portions 116₁ to 116₄, even if it is determined that a digital signal is not being input. The same switching voltage as the switching voltage to be set when the sound quality is low may be set as the switching voltage to be set when a digital signal is not being input. For example, the switching voltage setting portion 1046 sets the same switching voltage as the switching voltage to be set when the sound quality is low. Also, the DSP 104 may output a signal to turn off the switching portions 110 to the switching portions 110 of the amplifying portions 116₁ to 116₄. For example, the switching voltage setting portion 1046 outputs a signal to turn off the switching portions 110 of the amplifying portions 116₁ to 116₄.

In the example shown in FIG. 5, the driver only need be able to recognize voice guidance, so the carrier frequency and the switching voltage are set as described below for each amplifying portion 116₁ to 116₄.

The carrier frequency and the switching voltage to be set for the PWM modulator 108 and the switching portion 110 of the amplifying portion 116₁ may be set to the respective operating levels required for voice guidance. Also, the carrier frequency and the switching voltage to be set for the PWM modulator 108 and the switching portion 110 of the amplifying portion 116₂ may be set to the respective operating levels when sound is muted, or the PWM modulator 108 and the adjacent portions 110 may be stopped. Also, the carrier frequency and the switching voltage to be set for the PWM modulator 108 and the switching portion 110 of the amplifying portion 116₃ may be set to the respective operating levels when sound is muted, or the PWM modulator 108 and the adjacent portions 110 may be stopped. Also, the carrier frequency and the switching voltage to be set for the PWM modulator 108 and the switching portion 110 of the amplifying portion 116₄ may be set to the respective operating levels when sound is muted, or the PWM modulator 108 and the adjacent portions 110 may be stopped.

According to this example embodiment, an amplifier is provided that modulates a carrier frequency according to a digital signal, and amplifies the modulated signal.

This amplifier has a determining portion that determines at least one of a sound quality required for a digital signal, a sound source of the digital signal, and a type of sound of the digital signal, a carrier frequency setting portion that sets a carrier frequency according to a result of the determination by the determining portion, and a pulse-width modulating portion that pulse-width modulates the carrier frequency set by the carrier frequency setting portion.

Being able to set the carrier frequency to be used when modulating the carrier frequency according to the digital signal, according to at least one of the sound quality required for the digital signal, the sound source of the digital signal, and the type of sound of the digital signal enables power consumption to be reduced.

Moreover, the input signal determining portion that serves as a microcomputer and determines whether the digital signal is being input is provided. The carrier frequency setting portion sets the carrier frequency to a low frequency or stops oscillation when it is determined by the input signal determining portion that the digital signal is not being input.

When it is determined that a digital signal is not being input, the carrier frequency can be set to a low frequency or oscillation can be stopped, which enables power consumption to be reduced.

Furthermore, a switching power setting portion that sets the switching power to be used when amplifying the carrier frequency modulated by the pulse-width modulating portion, according to the result of the determination by the determining portion, and a switching portion that amplifies the carrier frequency modulated by the pulse-width modulating portion, according to the switching power set by the switching power setting portion are provided.

Being able to set the switching power to be used when amplifying the carrier frequency modulated by the pulse-width modulating portion, according to at least one of the sound quality required for the digital signal, the sound source of the digital signal, and the type of sound of the digital signal enables power consumption to be even further reduced.

According to this example embodiment, an amplifier is provided that modulates a carrier frequency according to a digital signal, and amplifies the modulated signal.

This amplifier has an input signal determining portion that determines whether the digital. signal is being input, a determining portion that determines at least one of a sound quality required for the digital signal, a sound source of the digital signal, and a type of sound of the digital signal, a carrier frequency setting portion that sets a carrier frequency according to a result of the determination by the determining portion, and a plurality of pulse-width modulating portions that pulse-width modulate the carrier frequency set by the carrier frequency setting portion. The carrier frequency setting portion sets a carrier frequency that corresponds to each of the plurality of pulse-width modulating portions.

Being able to set the carrier frequency to be used when modulating the carrier frequency according to the digital signal, for the plurality of pulse-width modulating portions, according to at least one of the sound quality required for the digital signal, the sound source of the digital signal, and the type of sound of the digital signal enables power consumption to be reduced.

Moreover, the carrier frequency setting portion sets the carrier frequency corresponding to a pulse-width modulating portion that corresponds to the digital signal, from among the plurality of pulse-width modulating portions, to a low frequency or stops oscillation.

Setting the carrier frequency used by the pulse-width modulating portion that corresponds to the amplifying portion that is to output a digital signal, from among the plurality of pulse-width modulating portions, enables the power consumption of the pulse-width modulating portion for which the carrier frequency is set to be reduced. The carrier frequency corresponding to low sound quality may be set, or oscillation may be stopped, for the pulse-width modulating portions other than the pulse-width modulating portion for which the carrier frequency is set.

According to this example embodiment, a method by which an amplifier modulates a carrier frequency according to a digital signal, and amplifies the modulated signal is provided.

This method includes a determining step for determining at least one of a sound quality required for the digital signal, a sound source of the digital signal, and a type of sound of the digital signal, a carrier frequency setting step for setting a carrier frequency according to a result of the determination from the determining step, and a pulse-width modulating step for pulse-width modulating the carrier frequency set in the carrier frequency setting step, according to the digital signal.

According to this example embodiment, a method by which an amplifier modulates a carrier frequency according to a digital signal, and amplifies the modulated signal is provided.

This method includes an input signal determining step for determining whether the digital signal is being input, a determining step for determining at least one of a sound quality required for the digital signal, a sound source of the digital signal, and a type of sound of the digital signal, a carrier frequency setting step for setting a carrier frequency according to a result of the determination from the determining step, and a pulse-width modulating step for pulse-width modulating the carrier frequency set in the carrier frequency setting step, according to the digital signal, by a corresponding pulse-width modulating portion, from among a plurality of pulse-width modulating portions that pulse-width modulate a carrier frequency according to the digital signal. In the carrier frequency setting step, a carrier frequency corresponding to each of the plurality of pulse-width modulating portions is set.

While the invention has been described with reference to specific embodiments thereof, these example embodiments are for illustrative purposes only. It should be understood that the invention embraces various modifications, improvements, substitutions, and arrangements that may be conceived by one skilled in the art. To simplify the description, the apparatus according to the example embodiments of the invention has been described with reference to a functional block diagram, but this kind of apparatus may also be realized by hardware, software, or a combination of both hardware and software. The invention is not limited to the example embodiments described above, but may be embodied with various modifications, improvements, substitutions, or arrangements, without departing from the spirit of the invention.

1. An amplifier that modulates a carrier frequency according to a digital signal and amplifies the modulated signal, comprising:
a determining portion that determines at least one of a sound quality required for the digital signal, a sound source of the digital signal, and a type of sound of the digital signal;
a carrier frequency setting portion that sets a carrier frequency according to a result of the determination by the determining portion;
a pulse-width modulating portion that pulse-width modulates the carrier frequency set by the carrier frequency setting portion, according to the digital signal;
a switching power setting portion that sets a switching power to be used when amplifying the carrier frequency modulated by the pulse-width modulating portion, according to the result of the determination by the determining portion; and
a switching portion that amplifies the carrier frequency modulated by the pulse-width modulating portion, according to the switching power set by the switching power setting portion.

2. The amplifier according to claim 1, further comprising:
an input signal determining portion that determines whether the digital signal is being input,
wherein the carrier frequency setting portion sets the carrier frequency to a low frequency or stops oscillation, when it is determined by the input signal determining portion that the digital signal is not being input.

3. (canceled)

4. An amplifier that modulates a carrier frequency according to a digital signal and amplifies the modulated signal, comprising:
an input signal determining portion that determines whether the digital signal is being input;
a determining portion that determines at least one of a sound quality required for the digital signal, a sound source of the digital signal, and a type of sound of the digital signal;
a carrier frequency setting portion that sets a carrier frequency according to a result of the determination by the determining portion; and
a plurality of pulse-width modulating portions that pulse-width modulate the carrier frequency set by the carrier frequency setting portion, according to the digital signal,
wherein the carrier frequency setting portion sets a carrier frequency corresponding to each of the plurality of pulse-width modulating portions.

5. The amplifier according to claim 4, wherein the carrier frequency setting portion sets the carrier frequency corresponding to a pulse-width modulating portion that corresponds to the digital signal, from among the plurality of pulse-width modulating portions, to a low frequency or stops oscillation.

6. A method by which an amplifier modulates a carrier frequency according to a digital signal and amplifies the modulated signal, comprising:
determining at least one of a sound quality required for the digital signal, a sound source of the digital signal, and a type of sound of the digital signal;
setting a carrier frequency according to a result of the determination;
pulse-width modulating the set carrier frequency according to the digital signal;
setting a switching power to be used when amplifying the modulated carrier frequency, according to the result of the determination; and
amplifying the modulated carrier frequency, according to the set switching power.

7. A method by which an amplifier modulates a carrier frequency according to a digital signal and amplifies the modulated signal, comprising:
determining whether the digital signal is being input;
determining at least one of a sound quality required for the digital signal, a sound source of the digital signal, and a type of sound of the digital signal;
setting a carrier frequency according to a result of the determination; and
pulse-width modulating the set carrier frequency according to the digital signal, by a corresponding pulse-width modulating portion, from among a plurality of pulse-width modulating portions that pulse-width modulate the carrier frequency according to the digital signal,
wherein in setting the carrier frequency, a carrier frequency corresponding to each of the plurality of pulse-width modulating portions is set.
